(19) United States
(12) Patent Application Publication
(10) Pub. No.: US 2026/0211067 A1
(43) Pub. Date: Jul. 23, 2026

(54) DEEP LEARNING ENABLED B0 MAPPING

(71) Applicant: Siemens Healthineers AG, Forchheim (DE)

(72) Inventors: Thorsten Feiweier, Poxdorf (DE); Bryan Clifford, Belmont, MA (US); Cornelius Eichner, Fürth (DE); Heiko Meyer, Uttenreuth (DE); Omar Darwish, London (GB); Mahmoud Mostapha, Princeton, NJ (US); Mariappan S. Nadar, Plainsboro, NJ (US); Nirmal Janardhanan, Monmouth Junction, NJ (US); Yahang Li, Plainsboro, NJ (US); Laszlo Lazar, Gheorgheni (RO); Radu Miron, Iasi (RO)

(21) Appl. No.: 19/032,475

(22) Filed: Jan. 21, 2025

(51) Int. Cl. G01R 33/44; G01R 33/56; G01R 33/565

(52) U.S. Cl. CPC G01R 33/443; G01R 33/5608; G01R 33/56563

(57) ABSTRACT

Systems and methods for correction of a magnetic field for an MRI procedure. Two reference acquisitions are acquired having different readout gradients, for example with reversed polarity. A machine learning network generates a displacement map from the two reference acquisitions. A spatial distortion map of the magnetic field is generated by the displacement map. The spatial distortion map of the magnetic field may be used for correction of the magnetic field or processing of further acquired images.

### FIELD

This disclosure relates to medical imaging.

### BACKGROUND

In MRI, B0 field estimation refers to the process of measuring and mapping the strength and variations of the main static magnetic field (B0). B0 field estimation is typically accomplished using specialized pulse sequences that generate phase differences between different tissue types based on their local field variations, allowing for detailed visualization of field inhomogeneities within the scanned region.

Knowledge about the spatial variation of the magnetic B0 field is essential for various MR techniques. This holds true not only for mild variations (which are relevant e.g., in the context of susceptibility-induced distortions in echoplanar imaging (EPI)), but also for severe variations originating from the magnet design, that are typically present far from isocenter. For instance, this applies to the imaging (or spectroscopy) of anatomy which is implicitly located at an off-center position (e.g., shoulder imaging) or if the anatomy requires a large field of view (FOV).

In these regions, for example that are far from the isocenter, the B0 maps may be used for various corrective tasks, including (static or dynamic) shimming, image corrections (e.g., distortion corrections) or markup/masking of locations with severe field deviations. In addition to very sensitive imaging methods like EPI that are affected, even “robust” techniques like turbo spin-echo (TSE) acquisition may suffer from severe field variations. The pixel bandwidth (BW) along the readout dimension characterizes their sensitivity and may be limited by hardware restrictions and noise considerations. Typical BW ranges from ~100 Hz/pixel to ~1000 Hz/pixel. At off-center position, an anatomy may be exposed to fields deviating by several tens of parts per million (ppm) from its nominal value at isocenter. At 3T, a deviation of 20 ppm evaluates results in a field offset of ~2500 Hz, while a shift by 2.5 pixels at BW=1000 Hz/pixel may still appear small, stronger field deviations and/or lower BW immediately may result in non-negligible image distortions which may require mitigation by (local) shimming or image processing.

### SUMMARY

By way of introduction, the preferred embodiments described below include methods, systems, instructions, and/or computer readable media for B0 field estimation and correction using reference acquisitions with different readout gradients, for example readout-reversed reference acquisitions.

In a first aspect, a method for estimation of a spatial distribution of a magnetic field, the method comprising: acquiring, by an MR scanner, a first set of images with a first readout gradient; acquiring, by the MR scanner, a second set of images with a second readout gradient, wherein the second readout gradient is different from the first readout gradient; and estimating, by a machine learning network, a set of spatial B0 maps based on the first set of images and the second set of images.

In a second aspect, a system for estimation of a spatial distribution of a magnetic field, the system comprising: a MRI scanner configured to acquire a first image with a first readout gradient and a second image with a second readout gradient, wherein the second readout gradient is different from the first readout gradient; a memory configured to store a machine learning network configured as an image to image network, the machine learning network configured to input the first image and the second image and output a displacement map that characterizes a transformation of the first image to the second image; and a processor configured to apply the machine learning network to the first image and second image to generate the displacement map, the processor further configured to generate a B0 field map from the displacement map.

In a third aspect, a non-transitory computer readable storage medium comprising a set of computer-readable instructions stored thereon for estimation of a spatial distribution of a magnetic field, the computer-readable instructions which, when executed by at least one processor cause the at least one processor to: estimate, using a machine learning network, the spatial distribution of the magnetic field for an MRI system based on a first set of images and a second set of images, wherein first set of images is acquired with a first readout gradient and the second set of images is acquired with a second readout gradient, wherein the second readout gradient is different from the first readout gradient.

Any one or more of the aspects described above may be used alone or in combination. These and other aspects, features and advantages will become apparent from the following detailed description of preferred embodiments, which is to be read in connection with the accompanying drawings. The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the embodiments. Moreover, in the figures, like reference numerals designate corresponding parts throughout the different views.

FIG. 1 depicts an example of two TSE-based acquisition acquisitions with inverted polarity of the readout gradients GR according to an embodiment.

FIG. 2 depicts an example system for correction of a magnetic field based on readout-reversed reference acquisitions according to an embodiment.

FIG. 3 depicts an example workflow for estimation of a magnetic field based on readout-reversed reference acquisitions according to an embodiment.

FIG. 4 depicts an example artificial neural network according to an embodiment.

FIG. 5 depicts an example convolutional network according to an embodiment.

FIG. 6 depicts an example workflow for shimming using an estimated magnetic field according to an embodiment.

FIG. 7 depicts an example method for estimation of a magnetic field based on readout-reversed reference acquisitions according to an embodiment.

FIG. 8 depicts an example U-net architecture according to an embodiment.

### DETAILED DESCRIPTION

Embodiments described herein provide systems and methods that provide a correction of the magnetic field using reference acquisitions with different readout gradients.

In certain MRI techniques, geometric distortions occur that are deviations from rectilinear mapping caused by a combination of local off-resonances. For example, shim imperfections combined with the relatively low readout bandwidth of an EPI train along the phase encode direction may result in a spatial shift of the reconstructed voxel along that direction. In particular, MRI images may be distorted due to B0 inhomogeneities. While signals lost to these inhomogeneities cannot be recovered, signals that has been merely displaced may be returned to its proper location in the image if a map of the B0 field has been acquired. The B0 map, which may be referred to as a field map, may be derived from a spatial distortion map or displacement map. The signal displacements may affect multiple different types of MRI procedures. Echo planar imaging (EPI), in particular is heavily affected and thus the target of research in this area. EPI is a widely used pulse sequence for neuroimaging applications that utilizes relatively high-speed image acquisition that, for example, allows an entire brain to be imaged in under two seconds. This relatively high acceleration allows clinicians to measure metabolic, microstructural, functional, and/or physiologic parameters in clinically realizable scan times. Diffusion tensor imaging (DTI), diffusion-weighted imaging (DWI), functional MRI (fMRI), and dynamic susceptibility contrast (DSC) imaging all utilize EPI and are commonly used for white matter fiber tract mapping, connectivity, or motor/language function mapping, and measurement of blood flow or volume, respectively, prior to surgery. Unfortunately, this relatively high acceleration may come at a significant cost, as EPI may be prone to imaging artifacts.

Geometric distortions may lead to errors when registering functional or diffusion-weighted imaging data to an undistorted anatomical scan and limit the applications of MRI techniques such as EPI and others since they generally require some sort of correction. For EPI in particular, methods have been used that provide estimating a distortion map for distortion correction using phase-based methods. Such methods use the evolution of the MR signal phase with time to estimate spatial field variations, for example such as ΔB0(r): φ(r, t)=γΔB0(r) t. Since the absolute signal phase may be affected by multiple origins (e.g., coil sensitivities), multiple acquisitions with different evolution times are usually required, and relative signal phases are used for the field estimation. These drawbacks and others such as requiring careful consideration of phase wraps, careful consideration of spin species with different chemical shifts, and a lack of robustness in regions with large field deviations lead to subpar or inefficient procedures. Other attempts have been made for the estimation of displacement maps (which are equivalent to B0 maps for EPI acquisitions) using a deep learning technique based on phase-reversed EPI acquisitions. However, these methods use phase-reversed acquisitions, only apply to EPI, and cannot capture large field deviations.

Instead of phase-reversed acquisitions, embodiments described herein use reference acquisitions with different readout gradients. In an example, the reference acquisitions with different readout gradients use readouts that are inverted, e.g., reversed. Readout-reversal is not limited to EPI but may be applied to any imaging technique, including gradient-echo (GRE), spin-echo (SE), or turbo-spin-echo (TSE). In particular, techniques utilizing spin refocusing (SE, TSE) may acquire data in regions with strong field deviations and are thus suitable for mapping the B0 field in these areas according to embodiments described herein.

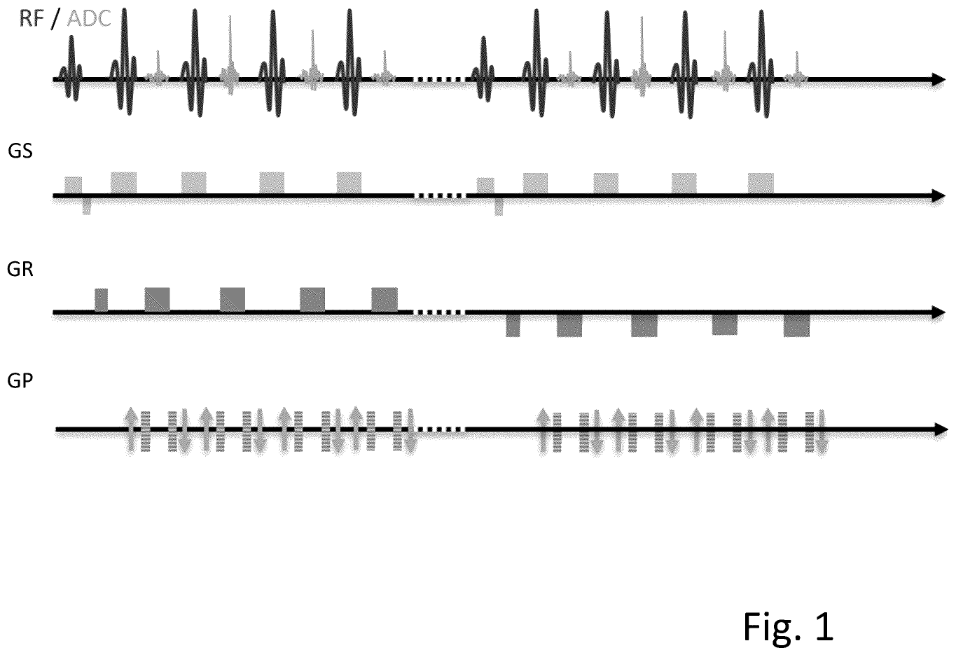

FIG. 1 depicts an example of two TSE-based acquisition acquisitions with inverted polarity of the readout gradients GR (i.e., inverse bandwidth along the frequency-encoding axis). FIG. 1 further depicts the slice selection gradients GS, phase encoding tables GP as well as RF-pulses and MR signal sampling. In magnetic resonance imaging (MRI), the readout gradient GR (also referred to as the “frequency encoding gradient”) directly affects the precession frequency of nuclei based on their location along a specific axis, essentially “encoding” spatial information by assigning different frequencies to different positions along that axis. This may be contrasted with the phase encoding gradient GP which manipulates the phase of the nuclei, allowing for spatial encoding along another axis by creating a phase shift that varies with position. The phase encoding gradient is used to impart a specific phase angle to a transverse magnetization vector. The specific phase angle depends on the location of the transverse magnetization vector. The frequency encoding gradient GR is used during data acquisition to read out the signal, while the phase encoding gradient GP is applied before data acquisition to prepare the signal for readout.

Embodiments described herein provide a robust and fast estimation of the spatial distribution of the magnetic field based on acquisitions with different readout gradients. The “readout” gradient GR applies a spatial frequency encoding of spins. Depending on their position r, spins are precessing with frequency f(\hat{r})=γ/(2π) \vec{Gᵣ} \vec{r}=γ/(2π) G_{R} \vec{Ê_{R}} \hat{r} where γ is the gyromagnetic ratio and \vec{ê_{R}} represents the unit vector along the readout direction. Any kind of field variation ΔB0(r) will apply an offset Δf(\vec{r})=γ/(2π) ΔB0(r) to the local precession frequency which results-after transforming the data from k-space to image space—in a local image distortion along \vec{ê_{R}}: f(\vec{r})+Δf(\vec{r})=γ/(2π) (\vec{Gᵣ} \vec{r}+ΔB0(\vec{r}))=γ/(2π) G_{R} \vec{ê_{R}} (\vec{r}+Δ\vec{r}) with a local spatial offset Δ\vec{r}=\vec{ê_{R}} ΔB0(\vec{r})/G_{R}.

Embodiments described herein acquire two images D_{A}(\vec{r}) and D_{B}(\vec{r}) (also referred to as DA and DB) with different readout gradient amplitudes G_{R,A} and G_{R,B}, and use deep learning techniques for the generation of a displacement map M(\vec{r}) which characterize a transformation D_{A}(\vec{r})->D_{B}(\vec{r}) (or vice versa). Displacements Δr=ΔB0(r)/G_{R} along the readout direction \vec{ê_{R}} scale linearly with the frequency deviation Δf_{A/B}=γ/(2π) G_{R,A/B} Δr: thus, for each image, the displacements M_{A/B}(\vec{r}) are directly linked to the underlying field deviation ΔB0(\vec{r})=BW_{A/B} M_{A/B}(\vec{r}). That this equation assumes that M is specified in units of pixels and BW is specified in units of T/pixel. Conversion to the more commonly used BW in units of Hz/pixel requires multiplication by γ/(2π). With this, it is possible to obtain the desired spatial field variations ΔB0(\vec{r}): ΔB0(\vec{r})=(M_{B}(\vec{r})−M_{A}(\vec{r})) (BW_{A} BW_{B})/(BW_{B}−BW_{A})=M(\vec{r}) (BW_{A} BW_{B})/(BW_{B}−BW_{A}). Using inverted readout gradients G_{R,B}=−G_{R,A} (i.e., BW_{B}=−BW_{A}) this simplifies to ΔB0(\vec{r})=(M_{B}(\vec{r})−M_{A}(\vec{r})) (BW_{A} BW_{B})/(BW_{B}−BW_{A})=½ M(\vec{r}) BW_{A}.

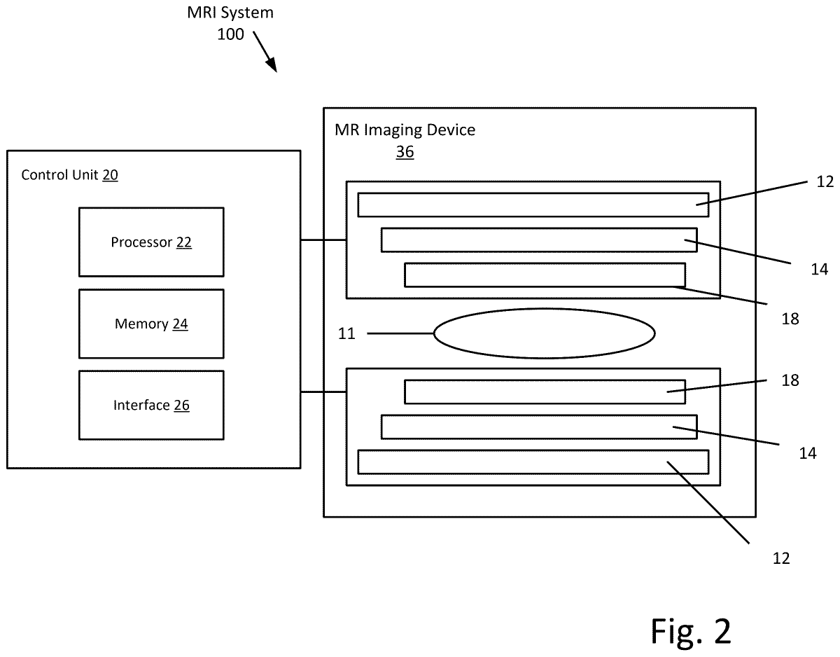

FIG. 2 depicts an example system 100 for deep learning enabled B0 mapping. MRI data is acquired by the MR system 100 using different readout gradients. A displacement map and/or a B0 map are generated by a deep learning model (as referred to as a machine learning network 300). The MR system 100 includes an MR scanner 36 or system, a computer configured for processing data acquired by MR scanning, a server, or another processor 22. The MR imaging device 36 is only exemplary, and a variety of MR scanning systems may be used to collect the MR data. The MR imaging device 36 (also referred to as a MR scanner or image scanner) is configured to scan a patient 11. The scan provides scan data in a scan domain. The MR imaging device 36 scans a patient 11 to provide k-space measurements (measurements in the frequency domain).

The MR system 100 further includes a control unit 20 configured to process the MR signals and generate (reconstruct) images of the object or patient 11 for display to an operator or further analysis. The control unit 20 is configured to implement or apply a machine learning network 300 to generate a B0 map. The control unit 20 includes a processor 22 that is configured to execute instructions, or the method described herein. The control unit 20 may store the MR signals and images in a memory 24 for later processing or viewing. The control unit 20 may include a display 26 for presentation of images to an operator.

In operation, magnetic coils 12 create a static base or main magnetic field B0 in the body of patient 11 or an object positioned on a table and imaged. Within the magnet system are gradient coils 14 for producing position dependent magnetic field gradients superimposed on the static magnetic field. Gradient coils 14, in response to gradient signals supplied thereto by a gradient and control unit 20, produce position dependent and shimmed magnetic field gradients in three orthogonal directions and generate magnetic field pulse sequences. The shimmed gradients compensate for inhomogeneity and variability in an MR imaging device magnetic field resulting from patient anatomical variation and other sources. In an embodiment, a generated B0 map is used for shimming an image region far from isocenter.

The control unit 20 may include a RF (radio frequency) module that provides RF pulse signals to RF coil 18. The RF coil 18 produces magnetic field pulses that rotate the spins of the nuclei in the imaged body of the patient 11 by ninety degrees or by one hundred and eighty degrees for so-called “spin echo” imaging, or by angles less than or equal to 90 degrees for “gradient echo” imaging. Gradient and shim coil control modules in conjunction with the RF module, as directed by control unit 20, control slice-selection, phase-encoding, readout gradient magnetic fields, radio frequency transmission, and magnetic resonance signal detection, to acquire magnetic resonance signals representing planar slices of the patient 11. In an embodiment, two acquisitions are performed with inverted readout gradient polarity in order to determine a B0 map which may be sued by the shim coil control modules to correct displacement or other issues. Magnetic field B0 homogenization, or shimming, describes the process of reducing its spatial variation by superposition of additional correction B0 fields that are provided using shim coils. A one-size-fits-all approach may not be applicable to B0 shimming due to intersubject variations in anatomy and subject positioning. Accurate mapping of the spatial pattern of the apparent field variation in the subject at hand is therefore necessary and a critical first step of the B0 shim procedure.

The control unit 20 may include a memory 24 and processor 22 configured to implement a machine learning network 300 that inputs a first set of images with a first readout bandwidth and a second set of images with a different readout bandwidth and is configured to estimate a displacement map and/or a set of spatial B0 maps from the two sets of images. As described above, a displacement map may first be generated by the machine learning model that characterize a transformation D_{A}(r)→D_{B}(r). The displacement map is used to generate a B0 map. Alternatively, the machine learning network 300 may directly generate the B0 map from the input images. The control unit 20 may include a processor 22, for example an image processor, that generates B0 maps using a machine learning network 300 (machine learning model/deep learning model/neural network/artificial neural network). The processor 22 is a general processor, digital signal processor, three-dimensional data processor, graphics processing unit, application specific integrated circuit, field programmable gate array, artificial intelligence processor, digital circuit, analog circuit, combinations thereof, or another now known or later developed device for image generation. The image processor is a single device, a plurality of devices, or a network. For more than one device, parallel or sequential division of processing may be used. Different devices making up the image processor may perform different functions. In one embodiment, the image processor is also a control processor or other processor of the imaging device. Other image processors of the imaging device or external to the imaging device may be used. The image processor is configured by software, firmware, and/or hardware to process the data acquired by the imaging device and output one or more images and quantitative map data.

The instructions for implementing the processes, methods, and/or techniques discussed herein are provided on non-transitory computer-readable storage media or memories, such as a cache, buffer, RAM, removable media, hard drive, or other computer readable storage media, for example as depicted as the memory 24. The instructions are executable by the processor 22 or another processor. Computer readable storage media include various types of volatile and nonvolatile storage media. The functions, acts or tasks illustrated in the figures or described herein are executed in response to one or more sets of instructions stored in or on computer readable storage media. The functions, acts or tasks are independent of the instructions set, storage media, processor or processing strategy and may be performed by software, hardware, integrated circuits, firmware, micro code, and the like, operating alone or in combination. In one embodiment, the instructions are stored on a removable media device for reading by local or remote systems. In other embodiments, the instructions are stored in a remote location for transfer through a computer network. In yet other embodiments, the instructions are stored within a given computer, CPU, GPU, or system. Because some of the constituent system components and method steps depicted in the accompanying figures may be implemented in software, the actual connections between the system components (or the process steps) may differ depending upon the manner in which the present embodiments are programmed.

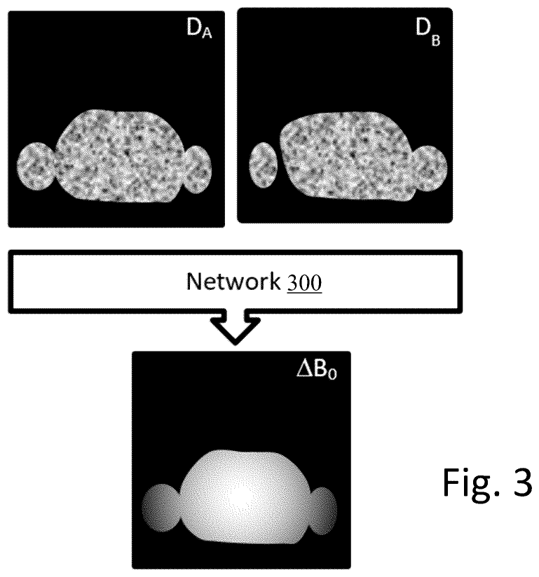

In an embodiment, a first set of images DA is acquired using a first readout gradient. A second set of imaged DB is acquired using a second readout gradient. The first readout gradient and the second readout gradient have opposite polarity. FIG. 3 depicts an example workflow of an embodiment for generating spatial distortion maps/B0 maps. An image to image network inputs the two sets of images and outputs a B0 map. As depicted in FIG. 3, both the first image (DA) and the second image (DB) are distorted at least at the edges of the images. For example, in the DA acquisition, the right side is “squished” or otherwise distorted, while the left side is “expanded”. Similarly, in DB, the left side is “squished”, while the right side is “expanded”. In an embodiment, the acquisitions may be repeated with different spatial alignments of the frequency encoding axis providing additional inputs for the image to image network. This may increase the precision of the B0 map. For example, three pairs of images with frequency encoding assigned to the physical x, y, and z axes (aligned with the fields generated by the three gradient coils) may be acquired. In an embodiment, a third set of images is acquired with a third readout gradient, wherein the first, second, and third readout gradients include frequency encoding with different amplitudes, polarities, and/or physical axes, wherein at least one of the readout gradients is applied along a physical x, y, or z axis different from the other two, wherein the machine learning network estimates the set of spatial B0 maps based on the first set of images, the second set of images, and the third set of images. In another embodiment, at least a third set of images with a third readout gradient and a fourth set of images with a fourth readout gradient are acquired, wherein at least one of the amplitude or the polarity of the fourth readout gradient is different from the third, wherein the at least third and the fourth readout gradient apply frequency encoding along the same physical x, y, or z axis which is different from the physical axis of the first and the second set images, wherein the machine learning network estimates the set of spatial B0 maps based on the first set of images, the second set of images, and the at least third and fourth sets of images. As an alternative, three pairs of images aligned with anatomical axes (e.g., axial, sagittal and coronal slice normals) may also be used. Especially if images get acquired with three-dimensional spatial encoding (i.e., using a volume-selective excitation and two phase-encoding gradient axes), two images acquired with different readout gradient directions (rather than amplitudes) may also be used as the network input.

The processor 22 uses one or more trained machine learning networks 300 for generating the displacement maps/spatial distortion maps/B0 maps, for example an image to image network(s), that are stored in the memory 24. In general, a trained machine learning network 300 mimics cognitive functions that humans associate with other human minds. In particular, by training based on training data the machine learning network 300 is able to adapt to new circumstances and to detect and extrapolate patterns. Another term for “trained machine learning network” is “trained function”. In general, parameters of a machine learning network can be adapted by means of training. In particular, supervised training, semi-supervised training, unsupervised training, reinforcement learning and/or active learning can be used. Furthermore, representation learning (an alternative term is “feature learning”) can be used. In particular, the parameters of the machine learning networks 300 can be adapted iteratively by several steps of training. In particular, within the training a certain cost function can be minimized. In particular, within the training of a neural network the backpropagation algorithm can be used. In particular, a machine learning network 300 may comprise a neural network, a support vector machine, a decision tree and/or a Bayesian network, and/or the machine learning network 300 can be based on k-means clustering, Q-learning, genetic algorithms and/or association rules. In an embodiment, the neural network may be a deep neural network, a convolutional neural network, or a convolutional deep neural network. Furthermore, a neural network may be an adversarial network, a deep adversarial network and/or a generative adversarial network. In particular, the network is an image to image network in that it inputs image(s) and outputs image (g).

Any type of suitable network may be used for inputting the two sets of images and outputting a displacement map/spatial distortion map/B0 map. The network(s) may be defined as a plurality of sequential feature units or layers. Sequential is used to indicate the general flow of output feature values from one layer to input to a next layer. The information from the next layer is fed to a next layer, and so on until the final output. The layers may only feed forward or may be bi-directional, including some feedback to a previous layer. The nodes of each layer or unit may connect with all or only a sub-set of nodes of a previous and/or subsequent layer or unit. Skip connections may be used, such as a layer outputting to the sequentially next layer as well as other layers. Rather than pre-programming the features and trying to relate the features to attributes, the deep architecture is defined to learn the features at different levels of abstraction the input data. The features are learned to reconstruct lower level features (i.e., features at a more abstract or compressed level). For example, features for generating a fused image or higher resolution image are learned. For a next unit, features for reconstructing the features of the previous unit are learned, providing more abstraction. Each node of the unit represents a feature. Different units are provided for learning different features.

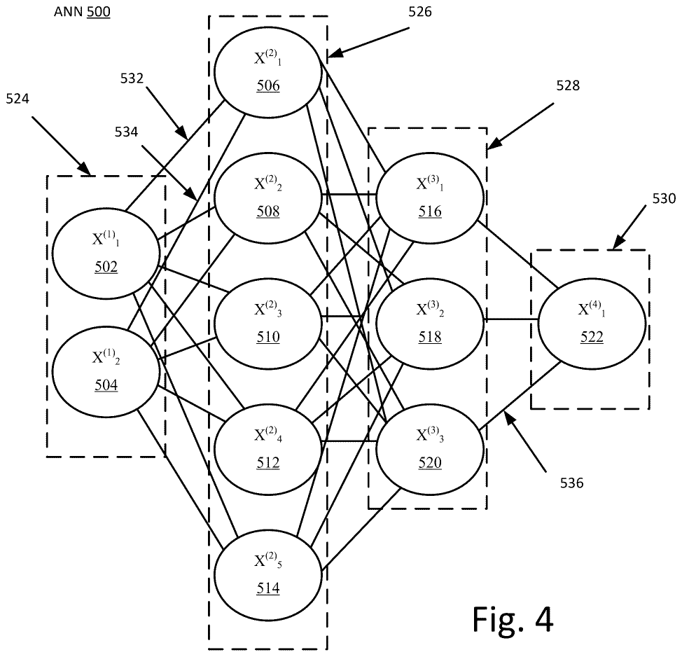

Various units or layers may be used, such as convolutional, pooling (e.g., max-pooling), deconvolutional, fully connected, or other types of layers. Within a unit or layer, any number of nodes is provided. For example, 100 nodes are provided. Later or subsequent units may have more, fewer, or the same number of nodes. In general, for convolution, subsequent units have more abstraction. FIG. 4 shows an embodiment of an artificial neural network (ANN) 500, in accordance with one or more embodiments. Alternative terms for “artificial neural network” are “neural network”, “artificial neural net” or “neural net”. The artificial neural network 500 may be used in part in, for example, the one or more machine learning based networks utilized for generating the displacement map/spatial distortion map/B0 map, etc.

The artificial neural network 500 includes nodes 502-522 and edges 532, 534, . . . , 536, wherein each edge 532, 534, . . . , 536 is a directed connection from a first node 502-522 to a second node 502-522. In general, the first node 502-522 and the second node 502-522 are different nodes 502-522, it is also possible that the first node 502-522 and the second node 502-522 are identical. For example, in FIG. 4, the edge 532 is a directed connection from the node 502 to the node 506, and the edge 534 is a directed connection from the node 504 to the node 506. An edge 532, 534, . . . , 536 from a first node 502-522 to a second node 502-522 is also denoted as “ingoing edge” for the second node 502-522 and as “outgoing edge” for the first node 502-522.

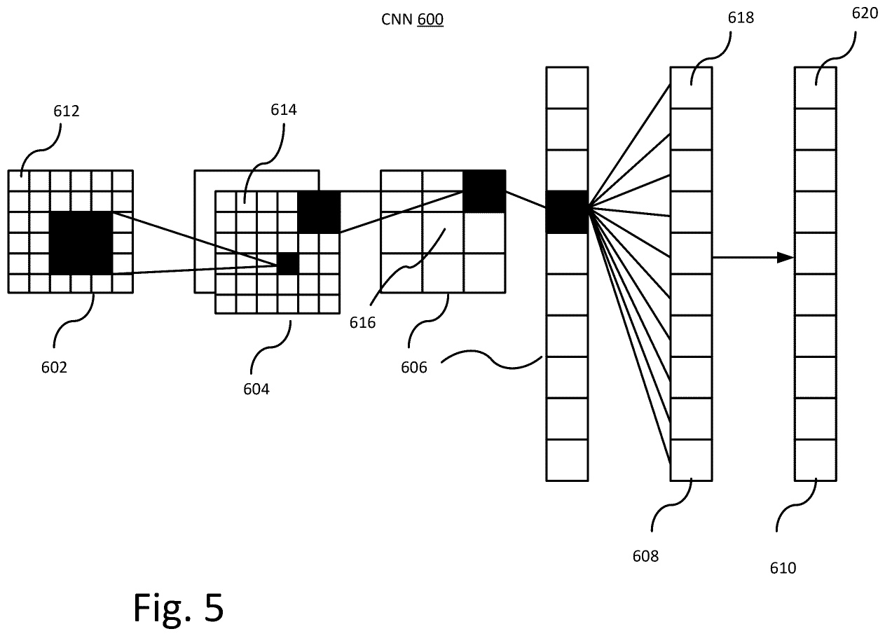

In this embodiment, the nodes 502-522 of the artificial neural network 500 may be arranged in layers 524-530, wherein the layers may include an intrinsic order introduced by the edges 532, 534, . . . , 536 between the nodes 502-522. In particular, edges 532, 534, . . . , 536 may exist only between neighboring layers of nodes. In the embodiment shown in FIG. 5, there is an input layer 524 including only nodes 502 and 504 without an incoming edge, an output layer 530 including only node 522 without outgoing edges, and hidden layers 526, 528 in-between the input layer 524 and the output layer 530. In general, the number of hidden layers 526, 528 may be chosen arbitrarily. The number of nodes 502 and 504 within the input layer 524 usually relates to the number of input values of the neural network 500, and the number of nodes 522 within the output layer 530 usually relates to the number of output values of the neural network 500.

In particular, a (real) number may be assigned as a value to every node 502-522 of the neural network 500. Here, x⁽ⁿ⁾ᵢ denotes the value of the i-th node 502-522 of the n-th layer 524-530. The values of the nodes 502-522 of the input layer 524 are equivalent to the input values of the neural network 500, the value of the node 522 of the output layer 530 is equivalent to the output value of the neural network 500. Furthermore, each edge 532, 534, . . . , 536 may include a weight being a real number, in particular, the weight is a real number within the interval [−1, 1] or within the interval [0, 1]. Here, w^{(m,n)}_{i,j} denotes the weight of the edge between the i-th node 502-522 of the m-th layer 524-530 and the j-th node 502-522 of the n-th layer 524-530. Furthermore, the abbreviation w⁽ⁿ⁾_{i,j} is defined for the weight w^{(n,n+1)}_{i,j}.

In particular, to calculate the output values of the neural network 500, the input values are propagated through the neural network. In particular, the values of the nodes 502-522 of the (n+1)-th layer 524-530 may be calculated based on the values of the nodes 502-522 of the n-th layer 524-530 by:

$${x}_{j}^{( n + 1 )} = f ( {\sum }_{i} {x}^{{( n )}_{j}} \cdot {w}^{{( n )}_{i , j}} ) .$$

Herein, the function f is a transfer function (another term is “activation function”). Known transfer functions are step functions, sigmoid function (e.g. the logistic function, the generalized logistic function, the hyperbolic tangent, the Arctangent function, the error function, the smoothstep function) or rectifier functions. The transfer function is mainly used for normalization purposes.

In particular, the values are propagated layer-wise through the neural network, wherein values of the input layer 524 are given by the input of the neural network 500, wherein values of the first hidden layer 526 may be calculated based on the values of the input layer 524 of the neural network, wherein values of the second hidden layer 528 may be calculated based in the values of the first hidden layer 526, etc.

In order to set the values w^{(m,n)}_{i,j} for the edges, the neural network 500 has to be trained using training data. In particular, training data includes training input data and training output data (denoted as tᵢ). For a training step, the neural network 500 is applied to the training input data to generate calculated output data. In particular, the training data and the calculated output data include a number of values, said number being equal with the number of nodes of the output layer.

In particular, a comparison between the calculated output data and the training data is used to recursively adapt the weights within the neural network 500 (backpropagation algorithm). In particular, the weights are changed according to

$${w}^{{′ ( n )}_{i , j}} = {w}^{{( n )}_{i , j}} - γ \cdot {δ}^{{( n )}_{j}} \cdot {x}^{{( n )}_{i}}$$

wherein γ is a learning rate, and the numbers δ⁽ⁿ⁾ⱼ may be recursively calculated as

$${δ}_{j}^{( n )} = ( {\sum }_{k} {δ}_{k}^{( n + 1 )} \cdot {w}^{{( n )}_{i , j}} ) \cdot {f}^{′} ( {\sum }_{i} {x}^{{( n )}_{j}} \cdot {w}^{{( n )}_{i , j}} )$$

based on δ⁽ⁿ⁺¹⁾ⱼ, if the (n+1)-th layer is not the output layer, and

$${δ}_{j}^{( n )} = ( {x}^{{( n + 1 )}_{j}} - {t}^{{( n + 1 )}_{j}} ) \cdot {f}^{′} ( {\sum }_{i} {x}^{{( n )}_{j}} \cdot {w}^{{( n )}_{i , j}} )$$

if the (n+1)-th layer is the output layer 530, wherein f′ is the first derivative of the activation function, and t⁽ⁿ⁺¹⁾ⱼ is the comparison training value for the j-th node of the output layer 530.

FIG. 5 shows an example convolutional neural network (CNN) 600, in accordance with one or more embodiments. Machine learning networks described herein, such as, e.g., the network 300 for generating a B0 map etc. may be implemented using the convolutional neural network 600. In the embodiment shown in FIG. 5 the convolutional neural network includes 600 an input layer 602, a convolutional layer 604, a pooling layer 606, a fully connected layer 608, and an output layer 610. Alternatively, the convolutional neural network 600 may include several convolutional layers 604, several pooling layers 606, and several fully connected layers 608, as well as other types of layers. The order of the layers may be chosen arbitrarily, usually fully connected layers 608 are used as the last layers before the output layer 610.

In particular, within a convolutional neural network 600, the nodes 612-620 of one layer 602-610 may be considered to be arranged as a d-dimensional matrix or as a d-dimensional image. In particular, in the two-dimensional case the value of the node 612-620 indexed with i and j in the n-th layer 602-610 may be denoted as x⁽ⁿ⁾_{[i,j]}. However, the arrangement of the nodes 612-620 of one layer 602-610 does not have an effect on the calculations executed within the convolutional neural network 600 as such, since these are given solely by the structure and the weights of the edges.

In particular, a convolutional layer 604 is characterized by the structure and the weights of the incoming edges forming a convolution operation based on a certain number of kernels. In particular, the structure and the weights of the incoming edges are chosen such that the values x⁽ⁿ⁾ₖ of the nodes 614 of the convolutional layer 604 are calculated as a convolution x⁽ⁿ⁾ₖ=Kₖ*x⁽ⁿ⁻¹⁾ based on the values x⁽ⁿ⁻¹⁾ of the nodes 612 of the preceding layer 602, where the convolution * is defined in the two-dimensional case as:

$${x}_{k}^{( n )} [ i , 1 ] = ( {K}_{k} ⋆ {x}^{( n - 1 )} ) [ i , j ] = {\sum }_{{i}^{′}} {\sum }_{{j}^{′}} {K}_{k} [ {i}^{′} , {j}^{′} ] \cdot {x}^{( n - 1 )} [ i - {i}^{′} , j - {j}^{′} ] .$$

Here the k-th kernel Kₖ is a d-dimensional matrix (in this embodiment a two-dimensional matrix), which is usually small compared to the number of nodes 612-620 (e.g. a 3×3 matrix, or a 5×5 matrix). In particular, this implies that the weights of the incoming edges are not independent, but chosen such that they produce said convolution equation. In particular, for a kernel being a 3×3 matrix, there are only 9 independent weights (each entry of the kernel matrix corresponding to one independent weight), irrespectively of the number of nodes 612-620 in the respective layer 602-610. In particular, for a convolutional layer 604, the number of nodes 614 in the convolutional layer is equivalent to the number of nodes 612 in the preceding layer 602 multiplied with the number of kernels.

If the nodes 612 of the preceding layer 602 are arranged as a d-dimensional matrix, using a plurality of kernels may be interpreted as adding a further dimension (denoted as “depth” dimension), so that the nodes 614 of the convolutional layer 604 are arranged as a (d+1)-dimensional matrix. If the nodes 612 of the preceding layer 602 are already arranged as a (d+1)-dimensional matrix including a depth dimension, using a plurality of kernels may be interpreted as expanding along the depth dimension, so that the nodes 614 of the convolutional layer 604 are arranged also as a (d+1)-dimensional matrix, wherein the size of the (d+1)-dimensional matrix with respect to the depth dimension is by a factor of the number of kernels larger than in the preceding layer 602.

The advantage of using convolutional layers 604 is that spatially local correlation of the input data may exploited by enforcing a local connectivity pattern between nodes of adjacent layers, in particular by each node being connected to only a small region of the nodes of the preceding layer.

In embodiment shown in FIG. 5, the input layer 602 includes 36 nodes 612, arranged as a two-dimensional 6×6 matrix. The convolutional layer 604 includes 72 nodes 614, arranged as two two-dimensional 6×6 matrices, each of the two matrices being the result of a convolution of the values of the input layer with a kernel. Equivalently, the nodes 614 of the convolutional layer 604 may be interpreted as arranges as a three-dimensional 6×6×2 matrix, wherein the last dimension is the depth dimension.

A pooling layer 606 may be characterized by the structure and the weights of the incoming edges and the activation function of its nodes 616 forming a pooling operation based on a non-linear pooling function f. For example, in the two dimensional case the values x⁽ⁿ⁾ of the nodes 616 of the pooling layer 606 may be calculated based on the values x⁽ⁿ⁻¹⁾ of the nodes 614 of the preceding layer 604 as

$${x}^{( n )} [ i , j ] = f ( {x}^{( n - 1 )} [ {id}_{1} , {jd}_{2} ] , … , {x}^{( n - 1 )} [ i {d}_{1} + {d}_{1} - 1 , j {d}_{2} + {d}_{2} - 1 ] )$$

In other words, by using a pooling layer 606, the number of nodes 614, 616 may be reduced, by replacing a number d1·d2 of neighboring nodes 614 in the preceding layer 604 with a single node 616 being calculated as a function of the values of said number of neighboring nodes in the pooling layer. In particular, the pooling function f may be the max-function, the average or the L2-Norm. In particular, for a pooling layer 606 the weights of the incoming edges are fixed and are not modified by training.

The advantage of using a pooling layer 606 is that the number of nodes 614, 616 and the number of parameters is reduced. This leads to the amount of computation in the network being reduced and to a control of overfitting.

In the embodiment shown in FIG. 5, the pooling layer 606 is a max-pooling, replacing four neighboring nodes with only one node, the value being the maximum of the values of the four neighboring nodes. The max-pooling is applied to each d-dimensional matrix of the previous layer.

A fully-connected layer 608 may be characterized by the fact that a majority, in particular, all edges between nodes 616 of the previous layer 606 and the nodes 618 of the fully-connected layer 608 are present, and wherein the weight of each of the edges may be adjusted individually.

In this embodiment, the nodes 616 of the preceding layer 606 of the fully-connected layer 608 are displayed both as two-dimensional matrices, and additionally as non-related nodes (indicated as a line of nodes, wherein the number of nodes was reduced for a better presentability). In this embodiment, the number of nodes 618 in the fully connected layer 608 is equal to the number of nodes 616 in the preceding layer 606. Alternatively, the number of nodes 616, 618 may differ.

A convolutional neural network 600 may also include a ReLU (rectified linear units) layer or activation layers with non-linear transfer functions. In particular, the number of nodes and the structure of the nodes contained in a ReLU layer is equivalent to the number of nodes and the structure of the nodes contained in the preceding layer. In particular, the value of each node in the ReLU layer is calculated by applying a rectifying function to the value of the corresponding node of the preceding layer.

The input and output of different convolutional neural network blocks may be wired using summation (residual/dense neural networks), element-wise multiplication (attention) or other differentiable operators. Therefore, the convolutional neural network architecture may be nested rather than being sequential if the whole pipeline is differentiable.

In particular, convolutional neural networks 600 may be trained based on the backpropagation algorithm. For preventing overfitting, methods of regularization may be used, e.g. dropout of nodes 612-620, stochastic pooling, use of artificial data, weight decay based on the L1 or the L2 norm, or max norm constraints. Different loss functions may be combined for training the same neural network to reflect the joint training objectives. A subset of the neural network parameters may be excluded from optimization to retain the weights pretrained on another datasets.

Referring back to FIG. 2, in response to applied RF pulse signals, the RF coil 18 of the MRI system 100 receives MR signals, e.g., signals from the excited nuclei within the body as the nuclei return to an equilibrium position established by the static and gradient magnetic fields. The MR signals are detected and processed by a detector within RF module and the control unit 20 to provide an MR dataset to the processor 22 for processing into an image. In some embodiments, the processor 22 is located in the control unit 20, in other embodiments, the processor 22 is located remotely. A two or three-dimensional k-space storage array of individual data elements in the memory 24 of the control unit 20 stores corresponding individual frequency components including an MR dataset. The k-space array of individual data elements includes a designated center, and individual data elements individually include a radius to the designated center. A magnetic field generator (including coils 12, 14 and 18) generates a magnetic field for use in acquiring multiple individual frequency components corresponding to individual data elements in the storage array. A storage processor in the control unit 20 stores individual frequency components acquired using the magnetic field in corresponding individual data elements in the array. The row and/or column of corresponding individual data elements alternately increases and decreases as multiple sequential individual frequency components are acquired. The magnetic field generator acquires individual frequency components in an order corresponding to a sequence of substantially adjacent individual data elements in the array, and magnetic field gradient change between successively acquired frequency components is substantially minimized.

The control unit 20 may use information stored in an internal database to process the detected MR signals in a coordinated manner to generate high quality images (2D/3D) of a selected slice(s) of the body (e.g., using the processor 22). The stored information may include a predetermined pulse sequence of an imaging protocol and a magnetic field gradient and strength data as well as data indicating timing, orientation, and spatial volume of gradient magnetic fields to be applied in imaging.

In an embodiment, the generated B0 maps from the two sets of acquired data are used for shimming, image correction, or other image processing. As detailed above, field inhomogeneities may result from both intrinsic magnet properties and the surrounding environment of the MR magnet-such as the presence of nearby metallic and electrical structures and the fields of nearby scanners. B0 field inhomogeneities cause signal loss and signal distortion. The B0 field map may be used to estimate the size of the distortion at each location and correct the signal location, for example using a pixel/voxel shift map. The B0 map may also be used to estimate signal loss, for example with a signal loss map. In another example, the B0 maps may be used to fine-tune the acquisition using shimming, for example using shim coils that generate their own magnetic field canceling certain field gradients in the main magnetic field. The B0 maps may be used to focus a subsequent scan, move a patient, or acquire additional information.

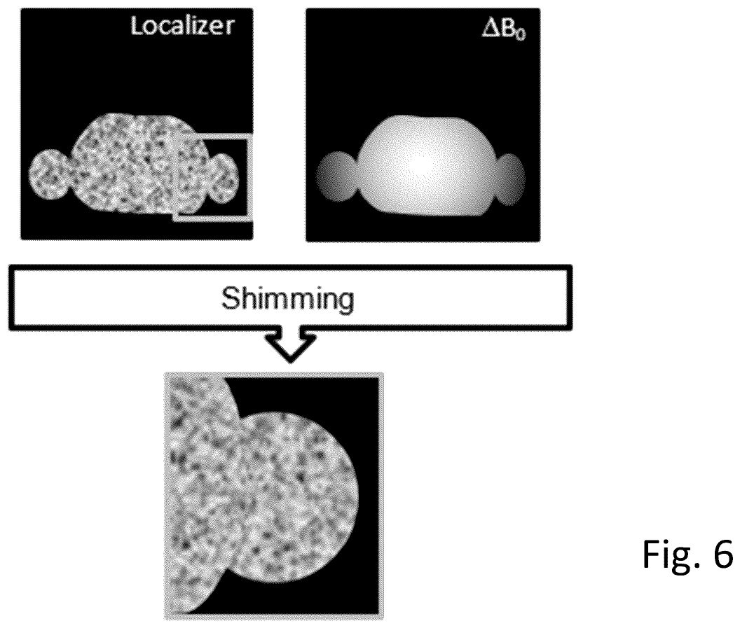

FIG. 6 depicts an example of the shimming using the generated B0 maps. The B0 map is converted into a set of shim functions that are applied by the scanner's shim coils to generate spatially varying fields that cancel out the measured inhomogeneity.

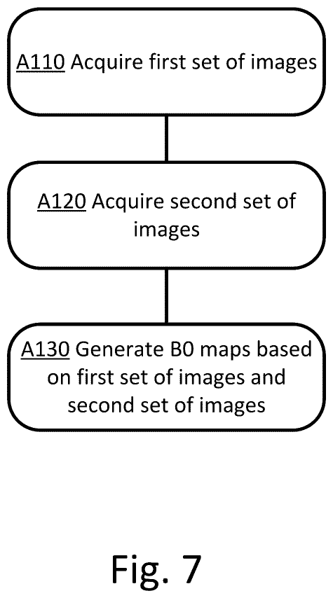

FIG. 7 depicts an example method for generating B0 maps using different readout gradients. The method is performed by the system 100 of FIG. 1 or another system. The method is performed in the order shown or other orders. Additional, different, or fewer acts may be provided.

The operator interface 26 includes an input device and an output device. The input may be an interface, such as interfacing with a computer network, memory, database, medical image storage, or other source of input data. The input may be a user input device, such as a mouse, trackpad, keyboard, roller ball, touch pad, touch screen, or another apparatus for receiving user input. The output is a display device but may be an interface. The images and/or B0 map may be displayed. The display is a CRT, LCD, plasma, projector, printer, or other display device. The display is configured by loading an image to a display plane or buffer. The display is configured to display the image of the region of the patient. The operator interface may include a graphical user interface (GUI) enabling user interaction with the MRI system 100.

At act A110, the MRI system 100 acquires a first set of images with a first readout gradient polarity. At act A120, the MRI system 100 acquires a second set of images with a second readout gradient polarity, wherein the second readout bandwidth is inverted from the first readout gradient polarity. In an embodiment, two images D_{A}(\vec{r}) and D_{B}(\vec{r}) are acquired with different readout gradient amplitudes G_{R,A} and G_{R}. A displacement map M(\vec{r}) which characterize a transformation D_{A}(\vec{r})→D_{B}(\vec{r}) is generated. The displacements M_{A/B}(\vec{r}) are directly linked to the underlying field deviation DB0(\vec{r})=BW_{A/B} M_{A/B}(\vec{r}). Note that this equation assumes that M is specified in pixels and BW in T/pixel. Conversion to the more commonly used BW in Hz/pixel requires multiplication by γ/(2π). With this, it is possible to obtain the desired spatial field variations DB0(\vec{r}): DB0(\vec{r})=(M_{B}(\vec{r})−M_{A}(\vec{r})) (BW_{A} BW_{B})/(BW_{B}−BW_{A})=M(\vec{r}) (BW_{A} BW_{B})/(BW_{B}−BW_{A}). Using inverted readout gradients G_{R,B}=−G_{R,A} (i.e., BW_{B}=−BW_{A}) this simplifies to DB0(\vec{r})=(M_{B}(\vec{r})−M_{A}(\vec{r})) (BW_{A} BW_{B})/(BW_{B}−BW_{A})=½ M(\vec{r}) BW_{A}.

In an embodiment, the acquisition uses gradient-echo (GRE), spin-echo (SE), or turbo-spin-echo (TSE). Spin echo sequences may include a slice selective 90-degree pulse followed by one or more 180 degree refocusing pulses. The TSE pulse sequence resembles a conventional spin-echo sequence in that it uses a series of 180°-refocusing pulses after a single 90°-pulse to generate a train of echoes. The TSE technique, however, changes the phase-encoding gradient for each of these echoes. The gradient echo is generated by the frequency-encode gradient, except that it is used twice in succession, and in opposite directions: it is used in reverse at first to enforce transverse dephasing of spinning nuclei and then right after, it is used as a readout gradient (like in spin-echo MRI) to re-align the dephased nuclei and hence acquire signal.

In an embodiment, the sets of images may be acquired using a (multi-slice) 2D or a 3D acquisition, respectively. Non-selective 3D acquisitions (i.e., not requiring slice selection gradients) don't suffer from slice bending effects, which may help increasing the spatial accuracy of acquired B0 maps.

In an embodiment, the sensitivity of the acquisition may be shaped by adapting the readout gradient amplitude (i.e., the pixel bandwidth along the frequency-encoding direction). This allows for selecting an appropriate compromise between image SNR (lower bandwidth yields higher SNR) and an accessible range of B0 variations. Combining B0-maps obtained with multiple pixel bandwidths may also be performed and may help extending the dynamic range of the method.

In an embodiment, the acquisitions are repeated with different spatial alignments of the frequency encoding axis. This may increase the precision of the B0 map. For example, three pairs of images with frequency encoding assigned to the physical x, y, and z axes (aligned with the fields generated by the three gradient coils) may be acquired. As an alternative, three pairs of images aligned with anatomical axes (e.g., axial, sagittal and coronal slice normals) may also be used.

In an embodiment, the set of images are acquired with a fat suppression method, (e.g., chemically-selective suppression, chemically-selective excitation, short-tau inversion-recovery (STIR)). One key aspect for the acquisition is the handling of chemical shift artifacts. Signal contributions from spins in a different chemical environment (e.g., water- and fat-bound hydrogen spins) will exhibit different precession frequencies, manifesting as a shifted appearance in the images. It is important that these shifts—which also depend on the readout gradient GR—are ignored when assessing the field maps based on B0-induced distortions. In an alternative embodiment, the chemical shift is considered when training the networks. This may include training on complex-valued data, since—depending on the acquisition technique—the image phase may comprise additional information on chemical shift.

In an embodiment, the impact of motion on the B0 map estimation may get reduced by applying a (rigid body) registration of DA and DB in advance. As an alternative, the k-space data of DA and DB may be sampled using an interleaved pattern, or by acquiring DA and DB data using one (multi-echo) sequence. In an example, this may be applicable to any of the sequences outlined above (GRE, SE, TSE). The at least two echoes are sampled immediately after each other, e.g. by applying a second readout gradient with inverted polarity immediately after the first readout gradient (and acquiring data during each of the two readout intervals).

At Act A130, a machine learning network 300 estimates a set of spatial B0 maps based on the first set of images and the second set of images. A displacement map may first be computed based on two images, for example using the machine learning network 300 (e.g., an image to image network). The B0 map may be derived or computed from the displacement map. As described above, in one or more example embodiments, the machine learning network 300 may be trained using a combination of supervised and unsupervised learning. Supervised learning is generally known in the art and may include training of the neural network that involves computing loss of the neural network by comparing an output of the neural network, such as the modified images, to a ground-truth image. Thus, for each input into the neural network, there is a corresponding desired output. Unsupervised learning is similarly generally known in the art and may involve computing loss of the neural network without requiring a corresponding desired output.

In one or more example embodiments, the neural network may be at least one of a general adversarial network (GAN), a multiscale generator model architecture, a GAN multiscale generator model with attention architecture, or a GAN generator model with attention and with recurrent convolutional layers architecture. In at least one example embodiment, the neural network may be a Pix2Pix GAN basic UNet generator model architecture, a Pix2Pix GAN attention UNet generator model architecture, or a Pix2Pix GAN attention R2UNet generator model architecture.

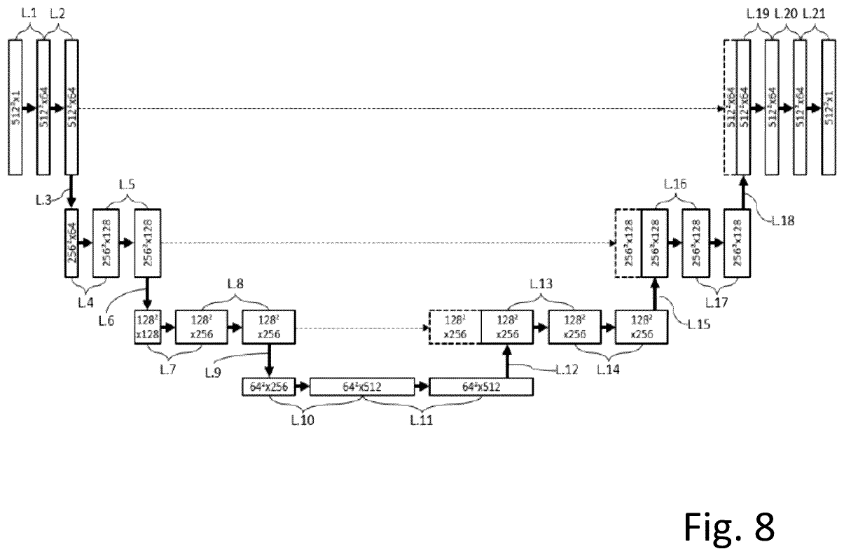

FIG. 8 depicts an example UNet architecture that may be used for the image to image network. In this example, the input data to the machine learning network 300 is a two-dimensional medical image comprising 512×512 pixel, every pixel comprising one intensity value. The machine learning network 300 comprises convolutional layers (indicated by solid, horizontal arrows), pooling layers (indicating by solid arrows pointing down), and upsampling layers (indicated by solid arrows pointing up), the number of the respective nodes is indicated within the boxes. Within the U-net structure first the input images are downsampled (decreasing the size of the im-ages and increasing the number of channels), afterwards they are upsampled (increasing the size of the images and decreasing the number of channels) to generate a transformed image.

All except the last convolutional layers L.1, L.2, L.4, L.5, L.7, L.8, L.10, L.11, L.13, L.14, L.16, L.17, L.19, L.20 use 3×3 kernels with a padding of 1, the ReLU activation function, and a number of filters/convolutional kernels that matches the number of channels of the respective node layers as indicated in FIG. 8. The last convolutional layer uses a 1×1 kernel with no padding and the ReLU activation function.

The pooling layers L.3, L.6, L.9 are max-pooling layers, replacing four neighboring nodes with only one node, the value being the maximum of the values of the four neighboring nodes. The upsampling layers L.12, L.15, L.18 are transposed convolution layers with 3×3 kernels and stride 2, which effectively quadruple the number of nodes. The dashed horizontal errors correspond to concatenation operations, where the output of a convolutional layer L.2, L.5, L.8 of the downsampling branch of the U-net structure is used as additional inputs for a convolutional layer L.13, L.16, L.19 of the upsampling branch of the U-net structure. This additional input data is treated as additional channels in the input node layer for the convolutional layer L.13, L.16, L.19 of the upsampling branch.

In one or more example embodiments, a neural network as described herein may be a Pix2Pix GAN basic UNet generator model architecture. The generator of this model architecture may include a whole image-to-image auto-encoder network with UNet skip connections to generate better image quality at higher resolutions. The Discriminator in the Pix2Pix GAN may include a PatchGAN Discriminator network that may output a classification matrix.

In one or more example embodiments, a neural network as described herein may alternatively be a Pix2Pix GAN attention UNet generator model architecture. This model architecture includes at least one attention gate. The one or more attention gates may be implemented at skip connections and may actively suppress activations in irrelevant regions. This may help to reduce the number of redundant features, which may reduce the computational resources wasted on irrelevant activations.

A Pix2Pix GAN attention R2UNet generator model architecture may utilize the power of UNet, Residual Network, as well as Recurrent Convolutional Neural Network (RCNN) with attention gates for the generator. In some example embodiments, the Pix2Pix GAN attention R2UNet generator model architecture may have several benefits. One benefit may be that the Pix2Pix GAN attention R2UNet generator model architecture includes a residual unit that may alleviate the problem of vanishing gradients seen in other deep learning models which may help with training deep architecture. An additional benefit may be feature accumulation with recurrent residual convolutional layers that may ensure better feature representation. Another benefit may be that the Pix2Pix GAN attention R2UNet generator model architecture may focus on the main areas of the images by using the attention gates. Each of these benefits helps to create a more stable U-Net architecture without changing the number of network parameters.

For any of the above-described model architectures, testing may be completed to evaluate the models. In at least one example embodiment, performance metrics used to evaluate the model architectures may include a structural similarity index measure (SSIM), DICE coefficient, mean absolute error (MAE), peak signal-to-noise ratio (PSNR), or Fréchet Inception Distance (FID). In at least one embodiment, hyperparameter tuning, ablation studies, and failure analysis may additionally be implemented to find limitations of any of the models. In at least one example embodiment, the loss metric that a neural network described herein is trained to reduce and/or minimize may include at least one of a discriminant loss, Wasserstein loss, or a loss computed using a pretrained (neural network) model (e.g., perceptual loss).

The output B0 map may be used for shimming, correction of images, or further processing. In an example, the processor 22 may generate a displacement field based on the B0 map and based on sequence acquisition parameters. In a further embodiment, in addition to or as an alternative, besides shimming and correcting, I the displacement map/B0 map may be used for masking or marking. The user receives information about the quality of the spatial alignment (marking) or data in regions with low spatial alignment is hidden (masking) depending on the B0 map. This may be a binary information (i.e., displacement is above or below a given displacement) or a more detailed information (e.g., a displacement category or even the actual displacement value).

While the invention has been described above by reference to various embodiments, many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention. Independent of the grammatical term usage, individuals with male, female or other gender identities are included within the term. The following is a list of non-limiting illustrative embodiments disclosed herein:
Illustrative embodiment 1: A method for estimation of a spatial distribution of a magnetic field, the method comprising: acquiring, by an MR scanner, a first set of images with a first readout gradient; acquiring, by the MR scanner, a second set of images with a second readout gradient, wherein the second readout gradient is different from the first readout gradient; and estimating, by a machine learning network, a set of spatial B0 maps based on the first set of images and the second set of images.
Illustrative embodiment 2. The method of illustrative embodiment 1, wherein the first readout gradient and the second readout gradient have inverted polarities.
Illustrative embodiment 3. The method of illustrative embodiment 1, wherein acquiring comprises acquiring with an imaging technique comprising gradient-echo (GRE), spin-echo (SE), or turbo-spin-echo (TSE).
Illustrative embodiment 4. The method of illustrative embodiment 1, further comprising: minimizing, using one or more shim coils, inhomogeneities in the magnetic field using the set of spatial B0 maps.
Illustrative embodiment 5. The method of illustrative embodiment 1, further comprising: scanning, by the MR scanner, a region of a patient; and correcting, using the set of spatial B0 maps, one or more images resulting from the scan of the region of the patient.
Illustrative embodiment 6. The method of illustrative embodiment 1, further comprising: acquiring, by the MR scanner, a third set of images with a third readout gradient, wherein the first, second, and third readout gradients include frequency encoding with different amplitudes, polarities, and/or physical axes, wherein at least one of the readout gradients is applied along a physical x, y, or z axis different from the other two, wherein the machine learning network estimates the set of spatial B0 maps based on the first set of images, the second set of images, and the third set of images.
Illustrative embodiment 7. The method of illustrative embodiment 1, further comprising: acquiring, by the MR scanner, at least a third set of images with a third readout gradient and a fourth set of images with a fourth readout gradient, wherein at least one of an amplitude or a polarity of the fourth readout gradient is different from the third, wherein the at least third and the fourth readout gradient apply frequency encoding along the same physical x, y, or z axis which is different from a physical axis of the first set of images and the second set of images, wherein the machine learning network estimates the set of spatial B0 maps based on the first set of images, the second set of images, and the at least third and fourth sets of images.
Illustrative embodiment 8. The method of illustrative embodiment 1, further comprising: generating, by the machine learning network, a displacement map based on the first set of images and the second set of images, wherein the set of spatial B0 maps is estimated based on the displacement map.
Illustrative embodiment 9. The method of illustrative embodiment 1, further comprising: adapting a readout gradient amplitude, direction, and/or polarity for the acquisition of the first set of images and the second set of images; and repeating the acquisitions of the first set of images and second set of images with the adapted readout gradient amplitudes.
Illustrative embodiment 10. The method of illustrative embodiment 1, further comprising: registering the first set of images and the second set of images prior to inputting the first set of images and second set of images into the machine learning network.
Illustrative embodiment 11. The method of illustrative embodiment 1, wherein the first set of images and the second set of images are acquired using a one multi-echo sequence.
Illustrative embodiment 12. The method of illustrative embodiment 1, wherein the first set of images and the second set of images are acquired using a chemically-selective suppression, chemically-selective excitation, short-tau inversion-recovery technique.
Illustrative embodiment 13. A system for estimation of a spatial distribution of a magnetic field, the system comprising: a MRI scanner configured to acquire a first image with a first readout gradient and a second image with a second readout gradient, wherein the second readout gradient is different from the first readout gradient; a memory configured to store a machine learning network configured as an image to image network, the machine learning network configured to input the first image and the second image and output a displacement map that characterizes a transformation of the first image to the second image; and a processor configured to apply the machine learning network to the first image and second image to generate the displacement map, the processor further configured to generate a B0 field map from the displacement map.
Illustrative embodiment 14. The system of illustrative embodiment 13, wherein the MRI scanner is configured to acquire the first image and second image using an imaging technique comprising gradient-echo (GRE), spin-echo (SE), or turbo-spin-echo (TSE).
Illustrative embodiment 15. The system of illustrative embodiment 13, wherein the MRI scanner is further configured, for a subsequent scan, to minimize, using one or more shim coils, inhomogeneities in the magnetic field using the B0 field map.
Illustrative embodiment 16. The system of illustrative embodiment 13, wherein the first readout gradient and the second readout gradient have inverted polarities.
Illustrative embodiment 17. The system of illustrative embodiment 13, wherein the first image and the second image are acquired using a chemically-selective suppression, chemically-selective excitation, short-tau inversion-recovery technique.
Illustrative embodiment 18. A non-transitory computer readable storage medium comprising a set of computer-readable instructions stored thereon for estimation of a spatial distribution of a magnetic field, the computer-readable instructions which, when executed by at least one processor cause the at least one processor to: estimate, using a machine learning network, the spatial distribution of the magnetic field for an MRI system based on a first set of images and a second set of images, wherein first set of images is acquired with a first readout gradient and the second set of images is acquired with a second readout gradient, wherein the second readout gradient is different from the first readout gradient.
Illustrative embodiment 19. The non-transitory computer readable storage medium of illustrative embodiment 18, wherein the first readout gradient and the second readout gradient have inverted polarities.
Illustrative embodiment 20. The non-transitory computer readable storage medium of illustrative embodiment 18, wherein the instructions which, when executed by at least one processor cause the at least one processor to further: minimize, using one or more shim coils of the MRI system, inhomogeneities in the magnetic field using the spatial distribution of the magnetic field.

1. A method for estimation of a spatial distribution of a magnetic field, the method comprising:
acquiring, by an MR scanner, a first set of images with a first readout gradient;
acquiring, by the MR scanner, a second set of images with a second readout gradient, wherein the second readout gradient is different from the first readout gradient; and
estimating, by a machine learning network, a set of spatial B0 maps based on the first set of images and the second set of images.

2. The method of claim 1, wherein the first readout gradient and the second readout gradient have inverted polarities.

3. The method of claim 1, wherein acquiring comprises acquiring with an imaging technique comprising gradient-echo (GRE), spin-echo (SE), or turbo-spin-echo (TSE).

4. The method of claim 1, further comprising:
minimizing, using one or more shim coils, inhomogeneities in the magnetic field using the set of spatial B0 maps.

5. The method of claim 1, further comprising:
scanning, by the MR scanner, a region of a patient; and
correcting, using the set of spatial B0 maps, one or more images resulting from the scan of the region of the patient.

6. The method of claim 1, further comprising:
acquiring, by the MR scanner, a third set of images with a third readout gradient, wherein the first, second, and third readout gradients include frequency encoding with different amplitudes, polarities, and/or physical axes, wherein at least one of the readout gradients is applied along a physical x, y, or z axis different from the other two, wherein the machine learning network estimates the set of spatial B0 maps based on the first set of images, the second set of images, and the third set of images.

7. The method of claim 1, further comprising:
acquiring, by the MR scanner, at least a third set of images with a third readout gradient and a fourth set of images with a fourth readout gradient, wherein at least one of an amplitude or a polarity of the fourth readout gradient is different from the third, wherein the at least third and the fourth readout gradient apply frequency encoding along the same physical x, y, or z axis which is different from a physical axis of the first set of images and the second set of images, wherein the machine learning network estimates the set of spatial B0 maps based on the first set of images, the second set of images, and the at least third and fourth sets of images.

8. The method of claim 1, further comprising:
generating, by the machine learning network, a displacement map based on the first set of images and the second set of images, wherein the set of spatial B0 maps is estimated based on the displacement map.

9. The method of claim 1, further comprising:
adapting a readout gradient amplitude, direction, and/or polarity for the acquisition of the first set of images and the second set of images; and
repeating the acquisitions of the first set of images and second set of images with the adapted readout gradient amplitudes.

10. The method of claim 1, further comprising:
registering the first set of images and the second set of images prior to inputting the first set of images and second set of images into the machine learning network.

11. The method of claim 1, wherein the first set of images and the second set of images are acquired using a one multi-echo sequence.

12. The method of claim 1, wherein the first set of images and the second set of images are acquired using a chemically-selective suppression, chemically-selective excitation, short-tau inversion-recovery technique.

13. A system for estimation of a spatial distribution of a magnetic field, the system comprising:
a MRI scanner configured to acquire a first image with a first readout gradient and a second image with a second readout gradient, wherein the second readout gradient is different from the first readout gradient;
a memory configured to store a machine learning network configured as an image to image network, the machine learning network configured to input the first image and the second image and output a displacement map that characterizes a transformation of the first image to the second image; and
a processor configured to apply the machine learning network to the first image and second image to generate the displacement map, the processor further configured to generate a B0 field map from the displacement map.

14. The system of claim 13, wherein the MRI scanner is configured to acquire the first image and second image using an imaging technique comprising gradient-echo (GRE), spin-echo (SE), or turbo-spin-echo (TSE).

15. The system of claim 13, wherein the MRI scanner is further configured, for a subsequent scan, to minimize, using one or more shim coils, inhomogeneities in the magnetic field using the B0 field map.

16. The system of claim 13, wherein the first readout gradient and the second readout gradient have inverted polarities.

17. The system of claim 13, wherein the first image and the second image are acquired using a chemically-selective suppression, chemically-selective excitation, short-tau inversion-recovery technique.

18. A non-transitory computer readable storage medium comprising a set of computer-readable instructions stored thereon for estimation of a spatial distribution of a magnetic field, the computer-readable instructions which, when executed by at least one processor cause the at least one processor to:
estimate, using a machine learning network, the spatial distribution of the magnetic field for an MRI system based on a first set of images and a second set of images, wherein first set of images is acquired with a first readout gradient and the second set of images is acquired with a second readout gradient, wherein the second readout gradient is different from the first readout gradient.

19. The non-transitory computer readable storage medium of claim 18, wherein the first readout gradient and the second readout gradient have inverted polarities.

20. The non-transitory computer readable storage medium of claim 18, wherein the instructions which, when executed by at least one processor cause the at least one processor to further:
minimize, using one or more shim coils of the MRI system, inhomogeneities in the magnetic field using the spatial distribution of the magnetic field.
